(19) United States
(12) Patent Application Publication
(10) Pub. No.: US 2013/0236720 A1
(43) Pub. Date: Sep. 12, 2013

(54) RARE-EARTH-FREE OR NOBLE METAL-FREE LARGE MAGNETIC COERCIVITY NANOSTRUCTURED FILMS

(71) Applicant: NORTHEASTERN UNIVERSITY, Boston, MA (US)

(72) Inventors: Donald HEIMAN, Newton, MA (US); Steven BENNETT, Brookline, MA (US); Thomas NUMMY, Newburgh, NY (US); Thomas CARDINAL, Altamont, NY (US)

(73) Assignee: NORTHEASTERN UNIVERSITY, Boston, MA (US)

(21) Appl. No.: 13/789,292

(22) Filed: Mar. 7, 2013

Related U.S. Application Data
(60) Provisional application No. 61/607,651, filed on Mar. 7, 2012.

(51) Int. Cl. H01F 1/047; H01F 41/22; C23C 16/48; B05D 3/02; C23C 16/06

(52) U.S. Cl. CPC H01F 1/047; B05D 3/0254; C23C 16/06; C23C 16/486; C23C 16/487; H01F 41/22
USPC 428/328; 427/130; 427/585; 427/597; 427/598; 252/62.55

(57) ABSTRACT

Rare-earth-free, noble-metal-free nanostructured magnetic material thin films and methods of synthesis are described. Magnetocrystalline, ferrimagnetic thin films with islands of aligned single magnetic domains possess large coercivity. In particular, MnₓGa thin films are described. These materials provide a potential substitute to rare-earth-based and noble-metal-based magnets in applications related to electric motors and generators, audio headphones and speakers, recording media and magnetic hard drive memory.

### CROSS-REFERENCE TO RELATED APPLICATION

This application claims priority from U.S. Provisional Application Ser. No. 61/607,651, filed Mar. 7, 2012, entitled “Large Magnetic Coercivity In Nanostructured Rare-Earth-Free MnₓGa Films” which is incorporated herein by reference.

### STATEMENT REGARDING FEDERALLY SPONSORED RESEARCH OR DEVELOPMENT

This invention was made in part with government support under Grant No. DMR-0907007, awarded by the National Science Foundation. The United States government has certain rights in this invention.

### BACKGROUND

This technology relates to magnetic materials. Rare-earth-based magnets provide the backbone of many products, from computers and mobile phones to electric cars and wind-powered generators. Noble-metal based materials are pervasive in magnetic memory devices. But because of the high cost and limited availability of rare-earth and noble metal elements, which are expensive to mine and process, there is a growing need to develop new magnetic materials without these elements.

### SUMMARY

Rare-earth-free, noble-metal-free nanostructured magnetic material thin films are described. The materials possess high coercivity and provide a potential substitute to rare-earth-based magnets in applications related to electric motors and generators, audio headphones and speakers, recording media and magnetic hard drive memory.

In one aspect, a magnetic material includes a rare-earth free, noble-metal-free magnetocrystalline, ferromagnetic thin film disposed on a non-epitaxial substrate, wherein the thin film comprises a plurality of single-magnetic-domain islands, and the coercivity of the thin film is greater than that of epitaxially-deposited thin-film samples of rare-earth-free magnetic materials.

In one or more embodiments, the thin film is a ferrimagnetic compound with tetragonal crystal symmetry.

In one or more embodiments, the thin film composition is MnₓY, wherein Y is one or more of Al, Ga, Ti, Fe, Co, Cr, V and x is between 1 and 3.

In one or more embodiments, the coercivity is 2.5-5 T.

In one or more embodiments, the islands are nanoscale.

In one or more embodiments, the islands are magnetically isolated.

In one or more embodiments, the islands are 20-100 nm in diameter.

In one or more embodiments, the islands are 20-60 nm in diameter.

In one or more embodiments, the remnant magnetization of the material is greater than one-half of saturation magnetization.

In another aspect, a magnetic material includes a rare-earth free, noble-metal-free magnetocrystalline, ferromagnic thin film disposed on a non-epitaxial substrate, wherein the thin film comprises a plurality of single-magnetic-domain islands and the magnetic domains are aligned with respect to each other.

In one or more embodiments, the magnetic domains are aligned perpendicular to the thin film thickness.

In one or more embodiments, the coercivity of the thin film is greater than that of epitaxially-deposited thin-film samples of rare-earth-free magnetic materials

In one or more embodiments, the coercivity of the thin film is 2.5-5 T.

In one or more embodiments, the thin film is a ferrimagnetic compound with tetragonal crystal symmetry.

In one or more embodiments, the thin film composition is MnₓY, wherein Y is one or more of Al, Ga, Ti, Fe, Co, Cr, V and x is between 1 and 3.

In one or more embodiments, the coercivity is 2.5-5 T.

In one or more embodiments, the islands are nanoscale.

In one or more embodiments, the islands are magnetically isolated.

In one or more embodiments, the islands are 20-100 nm in diameter.

In one or more embodiments, the islands are 20-60 nm in diameter.

In one or more embodiments, the remnant magnetization of the material is greater than one-half of saturation magnetization.

In another aspect, a method of producing a magnetic material includes depositing a noble-metal-free, rare-earth-free, magnetocrystalline, ferromagnetic thin film on a non-epitaxial substrate to form a plurality of single-magnetic-domain islands, and annealing the thin film.

In one or more embodiments, the thin film is a ferrimagnetic compound with tetragonal crystal symmetry.

In one or more embodiments, the thin film composition is MnₓY, wherein Y is one or more of Al, Ga, Ti, Fe, Co, Cr, V and x is between 1 and 3.

In one or more embodiments, the coercivity of the material is 2.5-5 T.

In one or more embodiments, the islands are magnetically isolated and are 20-100 nm in diameter.

In one or more embodiments, depositing includes one of molecular beam epitaxy, magnetron sputtering, electron bean evaporation, ion beam deposition, and chemical vapor deposition.

In one or more embodiments, the depositing is performed at 100-200° C.

In one or more embodiments, the annealing is performed below 450° C.

In one or more embodiments, the annealing is performed at 300-400° C.

In one or more embodiments, the substrate comprises silicon with amorphous native oxide layer or silica.

In one or more embodiments, annealing aligns the magnetic domains with respect to the each other.

In one or more embodiments, an external magnetic field is applied during growth or annealing to align the magnetic domains.

### BRIEF DESCRIPTION OF THE DRAWINGS

The features and advantages of certain embodiments are illustrated in the accompanying drawings, which are presented for the purpose of illustration only and are not intended to be limiting of the invention.

FIGS. 1(a)-1(e) show images and x-ray diffraction of a nanostructured MnₓGa, x=2.7, film grown on Si substrate, according to one or more embodiments of the current disclosure; (a) Nanostructures of island-like particles are pictured in the scanning electron microscope (SEM) image of the surface, where the bar is 200 nm. Reflection high energy electron diffraction (RHEED) images: (b) as-grown at 90° C.; and (c) annealed at 400° C. for 60 minutes showing distinct alignment of crystallites. (d) X-ray θ-2θ diffraction intensity showing MnₓGa(112), MnₓGa(200) and MnₓGa(224) diffraction peaks of the D0₂₂ structure. (e) Illustration of crystal structure of Mn₃Ga, where Ga atoms are the small grey spheres at the corners and the center.

FIG. 2 shows magnetic properties of a nanostructured MnₓGa, x=2.7, film illustrating the large coercivity at room temperature, according to one or more embodiments of the current disclosure. Magnetization (scaled and diamagnetism subtracted) of a nanostructured film grown on non-epitaxial Si (solid circles) compared to that of a highly-ordered film grown epitaxially on GaAs (open squares). The solid curves are guides for the eye. The nanostructured film has an order of magnitude larger coercive field, μₒH_{C}=2.5 T. The inset shows the temperature dependence of the remanent magnetization, M_{R}(H=0), of the nanostructured film, M_{R}(T)/M_{R}(O), (dark crosses), and the temperature dependence of the coercive field, H_{C}(T)/H_{C}(O), (open circles). The solid curves are empirical fits to (1−T/TT)^{α}, where T′=710 K and α=0.45 for MR (T), while T′=530 K and α=0.40 for H_{C}(T).

FIGS. 3(a)-3(c) shows large coercivity in the anomalous Hall effect (AHE) at room temperature for a nanostructured MnₓGa, x=2.7, film, according to one or more embodiments of the current disclosure. (a) Solid curve (black) shows the total Hall resistivity, arising from the anomalous Hall effect (AHE) plus reversible resistivity, and the dashed line (gray) illustrates the reversible resistivity component. (b) The solid curve shows the AHE resistivity component, and the circles show the closely matched magnetization. The magnitudes are scaled by the saturation values to provide comparison. (c) Magnetization of Stoner-Wohlfarth particles (or islands) for easy-axis aligned with field φ=0 (square, dashed curve), a φ=40 deg angle between easy axis and field (dotted curve), and random alignment of easy axes (solid curve).

### DETAILED DESCRIPTION

Because of the high cost and limited availability of rare-earth and noble metal elements, there is a growing need to develop new magnetic materials without these elements.

One of the key properties of super strong magnets is their large magnetocrystalline anisotropy. Thus, it is advantageous to have rare-earth-free, noble-metal-free ferromagnets with large anisotropies, such as MnₓY, wherein Y is one or more of Al, Ga, Ti, Fe, Co, Cr, V and x is between 1 and 3. However, in order to take advantage of the large anisotropy and make them suitable for applications they must be synthesized with an appropriate composition and structure at the nanoscale level.

A thin film of a rare-earth free, noble-metal-free magnetocrystalline, ferromagnic material disposed on a non-epitaxial substrate with a plurality of single-magnetic-domain islands was surprisingly found to possess a greater coercivity than epitaxially-deposited thin-film samples of rare-earth-free magnetic materials. As the magnitude of the coercivity approaches that found in rare-earth magnets, these materials find potential applications in mechanical and electrical devices that require high coercive fields.

When thin films of these materials were deposited/grown on non-epitaxial substrates, the films surprisingly formed isolated islands of the magnetocrystalline, ferromagnic material. In some embodiments, these islands are magnetically isolated and magnetic domains are aligned with respect to each other. Annealing of the film led to increased alignment of the magnetic domains.

In one embodiment, when the Heusler compound MnₓGa was synthesized with the proper nanostructuring, a remarkably high coercive field was produced. The remarkably large coercivity is attributed to the combination of large intrinsic magnetocrystalline anisotropy and suitable nanostructuring (suitable size and crystal orientation). These results suggest that MnₓGa and other related compounds are good candidates for producing materials with enhanced coercive fields aimed at replacing some rare-earth-based magnets in use today.

Heusler compounds find applications in magnetic shape-memory, thermoelectrics, semi and superconductivity, topological insulators, and half-metallicity. The binary ferrimagnet MnₓGa (x=2-3) is one of the simplest Heusler materials. This material possesses magnetocrystalline anisotropy. Thus, the atomic structure of the crystal introduces preferential directions for the magnetization (magnetic easy axis). Specifically, the crystalline c-axis of MnₓGa correlates to its magnetic easy (unique) axis. Additionally, its magnetism is tunable. For example, the saturation moment is predicted to be variable by as much as a factor of 4 in MnₓGa by varying the stoichiometry from x=2 to x=3.6.

MnₓGa is a ferrimagnet with tetragonal crystal symmetry (asymmetric). Ferrimagnetic materials are like ferromagnets in that they hold a spontaneous magnetization below the Curie temperature, and show no magnetic order (are paramagnetic) above this temperature. Herein, ferrimagnets are considered a subclass of ferromagnetic materials. A ferrimagnetic material is one in which the magnetic moments of the atoms on different sublattices are opposed, but because the opposing moments are unequal, a spontaneous magnetization remains. In the case of MnₓGa, the sublattices are those of the Mn atoms.

The structural and magnetic properties of MnₓGa have been produced as bulk materials and as thin films grown on various epitaxial substrates including Si, GaAs, GaN, GaSb, Al₂O₃, MgO, and Cr—MgO. When grown on lattice-matched substrates the resulting epitaxial films exhibited an easy-axis perpendicular to the film plane. Previous studies have shown that these oriented films can have large anisotropy fields extrapolating to μₒH_{A}=10 T or higher. Anisotropy is an intrinsic property of the material. This anisotropy field is an indication of how much energy is required to deflect the magnetic moment of the material from the easy to the hard axis. Other studies determined that an anisotropy constant of K˜107 erg/cm³ from H_{A}=2K/M_{S} and the saturation magnetization M_{S}. Saturation is the state reached when an increase in applied external magnetic field H cannot increase the magnetization of the material further. Since coercivity is an extrinsic property which depends on size and shape of the material structure, in practice, the coercive field or coercivity (the magnetic field required to reduce the magnetization to 0 after saturation) is typically limited to H_{C}/H_{A}˜0.3. Thus, MnₓGa is capable of having a coercive field of at least μₒH_{C}˜3-5 T.

In certain embodiments, MnₓGa films can be synthesized with islands having ˜20-100 nm, or preferably 20-60 nm dimensions (diameter). This is shown to be an appropriate size for generating remarkably large coercive fields, as large as μₒH_{C}=2.5 T, or up to 4-5T, which is nearly an order of magnitude larger than for well-ordered epitaxial films and bulk samples. The high coercive fields are attributed to the combination of specific nanostructuring and a large intrinsic magnetocrystalline anisotropy.

In one or more embodiments, the islands do not have interacting domains or superparamagnetic properties. The dimensions of the nanoscale islands-like particles play a role in achieving large coercive fields, as particles that are too large support multidomains (e.g., greater than 60-100 nm), while particle that are too small (e.g., less than 20 nm) become superparamagnetic at room temperature. Herein, nanoscale means below 1 μm and above 1 nm. Particles having multiple domains have the disadvantage of inter-domain interactions and a lowered coercivity. Superparamagnetic particles are not ferromagnetic, do not result in higher coercivity, and are highly influenced by thermal fluctuations.

In some embodiments, the nanostructured films have strained particle-like (or island-like) features.

Several mechanisms hinder the field-induced magnetic alignment that leads to hysteresis. In relatively large particles the hysteresis arises from magnetic domains, which are characterized by pinning of domain walls and nucleation of reversed domains. On the other hand, when particles are too small to support multiple domains, the hysteresis arises from coherent reversal of single magnetic domains that are hindered by anisotropy. Single-domain particles must be small enough to prohibit the formation of domain walls.

In certain embodiments, thin films of MnₓGa in the range x=1 to 3, or preferably 2-3, were deposited onto non-epitaxial substrates. The deposition method may include growth by molecular beam epitaxy (MBE), or may be magnetron sputtering, electron bean evaporation, ion beam deposition, or chemical vapor deposition. Molecular beam epitaxy and other deposition techniques can provide precise control of atomic ratios of the deposited material. This is advantageous in magnetocrystalline materials such as MnₓGa whose magnetism is tunable and where the saturation moment is predicted to be variable by as much as a factor of 4 by varying the stoichiometry from x=2 to x=3.6.

The growth may take place at elevated temperatures, preferably at 100-200° C.

The substrate may be silicon substrates having an amorphous native oxide surface layer. The substrate may also be any other amorphous material which does not deform under processing temperatures, such as silica.

The growth step produced a thin film with nanoscale islands which predominantly each comprise a single magnetic domain with a corresponding crystalline axis. It is believed that the thin film breaks up spontaneously into islands due to a lack of an epitaxial substrate. In some embodiments, these islands are physically and magnetically isolated from one another.

After growth, the thin films were annealed at temperatures between 300-400° C., preferably below 450° C. Annealing the films produced some increased alignment of the crystalline axes of the single domain island (and consequently their easy axes). In some cases, some alignment of the domains with respect to each other was observed after growth and before annealing. In other cases, the unannealed films show almost complete random alignment (no alignment). In some embodiments, the magnetic domains after growth/deposition and annealing are aligned with respect to each other. In other words, there is some defined direction of the average magnetic moment of the material (averaged over all the islands). Alignment is contrasted to completely random distribution of easy axis directions, with no average direction of the magnetic moments. In some embodiments, the alignment of magnetic moments of magnetic domains is perpendicular to the thin film.

In some embodiments, the average ensemble alignment of the annealed nanoparticles/islands was approximately 40 degrees. In other embodiments, 50% of the particles are primarily aligned along the easy axis direction Annealing may increase the total saturation magnetization of the material by several times Annealing generally affects the coercivity more that it affects the saturation magnetization. Coercivity can change by an order of magnitude, while saturation moment usually changes by a smaller factor.

It is believed that annealing allows for movement of the Mn atoms, allowing them to move to one preferred sublattice (as this lowers their potential energy), this increasing the magnetic moment of the material, which contributed to an increase in coercivity. It is believed Mn may move between its own sublattices or may alternatively switch positions with Ga atoms during annealing.

For device applications, an external magnetic field may be applied during the steps of growth or annealing to further align the magnetic moments, preferably perpendicular to the substrate.

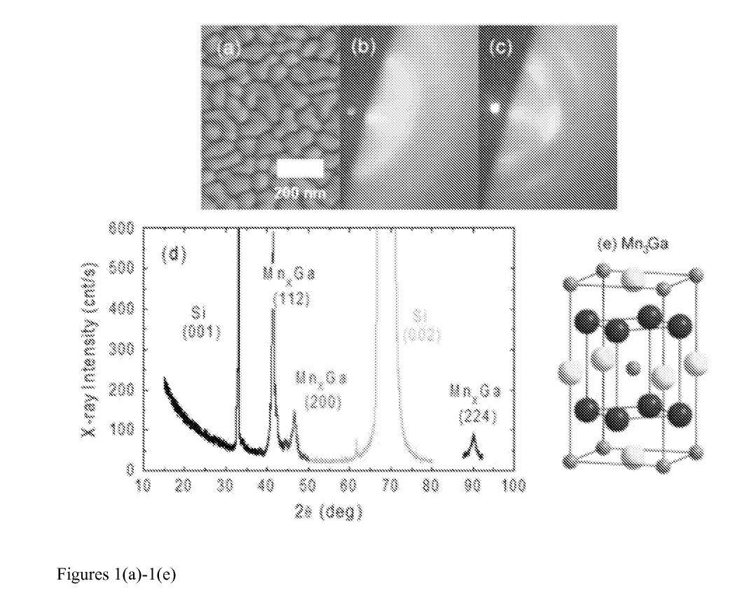

In one embodiment, a 20 nm thick MnₓGa film was grown by MBE on aSi (001) substrate having an amorphous native oxide surface layer is shown in the scanning electron microscope (SEM) image in FIG. 1(a). The particle-like structures are seen to have lateral dimensions on the order of ˜50-100 nm Annealing the films produced some alignment of the crystalline axes, as shown in the reflection high energy electron diffraction (RHEED) images of FIGS. 1(b-c). Before annealing, FIG. 1(b) shows a predominant random alignment displayed by the polycrystalline-like ring pattern. The nanocrystal orientation increased when the films were annealed at high temperatures. After annealing at 400° C., a fraction of the ring intensity coalesced into elongated spots as seen in FIG. 1(c). The annealed particles were found to have a distinct D0₂₂ crystal structure as determined from θ-2θ x-ray diffraction (XRD) shown in FIG. 1(d). The lattice constants of the D0₂₂ structure, illustrated in FIG. 1(e), were found to be a=0.389 nm and c=0.708 nm, indicating a ˜½% contraction in lattice constants compared to bulk values. Magnetization measurements were made in a superconducting quantum interference device (SQUID) magnetometer from Quantum Design. It was found that annealing led to increases in the saturation moment by as much as 10², up to values as high as M_{S}=130 emu/cm³.

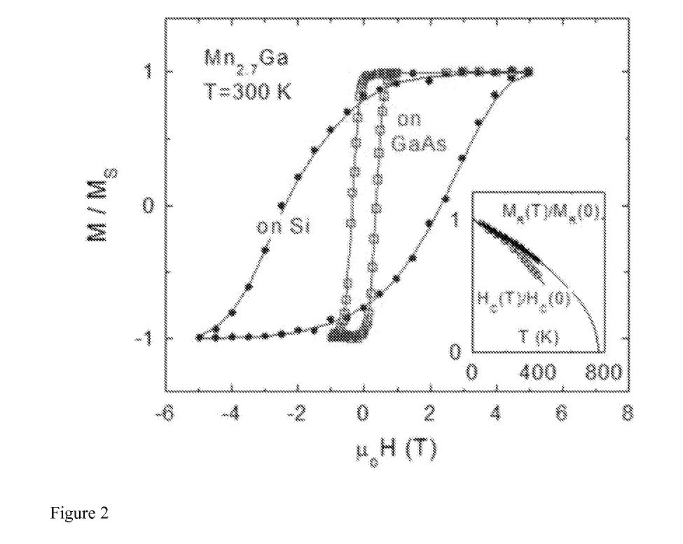

FIG. 2 illustrates the large coercivity in the magnetization that arises from the nanostructuring. This figure compares the room temperature magnetization, M(H), of a 20 nm thick nanostructured MnₓGa film, according to one embodiment, to that of a highly-ordered epitaxial film grown on GaAs. In contrast to the epitaxial sample, M(H) of the nanostructured film has a wide “s”-shaped major hysteresis (irreversibility) loop. The coercive field for the nanostructured film was exceptionally large, μₒH_{C}=2.5 T. This is much larger than the coercive field for the epitaxial film, μₒH_{C}=0.36 T, which is typical of other high-quality epitaxial films and bulk samples. The magnetism of nanostructured films was shown to be robust with respect to temperature. The inset of FIG. 2 plots the remanent magnetization, MR (H=0), as a function of temperature, MR(T). The moment remains high at T=400 K demonstrating a Curie temperature well above room temperature. The inset also shows the temperature dependence of the coercive field, HC(T), which appears to have a dependence similar to the remanence. The observed 2.5 T coercive field is on the order of those found in some important rare-earth permanent magnets, such as Nd₂Fe₁₄B where μₒH_{C}˜2.6 T, and SmCo₅ where μₒH_{C}˜4 T.

### Anomalous Hall Effect

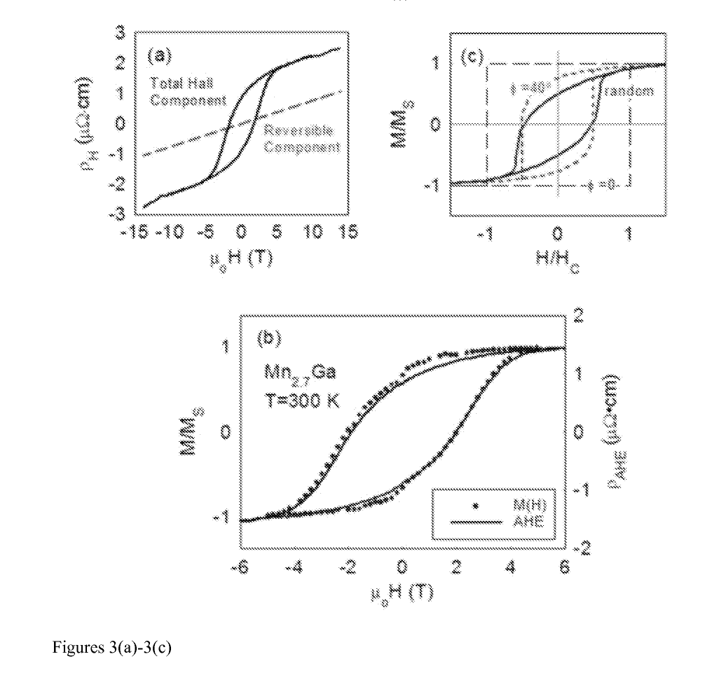

The large coercivity of nanostructured MnₓGa films was also present in the electronic properties through the anomalous Hall effect (AHE). The Hall effect in magnetic materials contains two main contributions, ρ_{H} (H)=Ro H+ R1 M(H,T), where Ro=−1/ne is the ordinary Hall effect (OHE) coefficient, n the carrier concentration, R1 the AHE coefficient, and M(H,T) the field and temperature-dependent magnetization. For magnetoconductivity measurements, van der Pauw squares and lithographically fabricated Hall bars with Ti—Au contacts were measured using a 14 T Cryogenics Limited Cryo-free magnet. Despite the particle-like (or island-like) growth, the films according to one or more embodiments had metallic conductivity with longitudinal resistivities in the range ρ=200 to 300 μΩ·cm. FIG. 3 shows results of room temperature Hall effect measurements of a 20 nm thick nanostructured MnxGa film, according to one or more embodiments. In FIG. 3(a) the raw Hall resistivity is plotted as a function of H applied perpendicular to the film. The AHE gave rise to the irreversible open-loop hysteresis, which closed up at μₒH_{C}=5 T. At higher fields the resistivity was reversible and linear in field.

The dashed line in FIG. 3(a) represents the total reversible component of the resistivity, which may contain some residual nonsaturating moment. From the slope of the reversible component lower limit for the effective carrier concentration, n≧8×10²¹ cm⁻³, was obtained, which corresponds to one electron per unit cell. In FIG. 3(b) the hysteresis in the AHE is compared with the magnetization. There is excellent agreement between data from the two measurements, including the magnitude of the coercive field for that sample. At high fields the AHE resistivity reached a saturation value of ρ_{AHE}=1.5 μΩ·cm.

### Particle Size Modeling

Energy minimization requires that single domain particles must be smaller than several times (≧3) the domain wall width. The width of the domain walls in MnₓGa is δ_{w}˜20-30 nm, using δw ˜2π(A/K₁)^{1/2} and A˜2×10⁻⁶ erg/cm as the exchange stiffness obtained from the magnetization and Curie temperature. A sizeable fraction of the MnₓGa particles are single domain since the domain wall width is a significant fraction of the particle size. For a single domain particle with uniaxial anisotropy the coercive field depends on the relative orientation between the unique (easy) magnetic axis and the applied field. For a field applied along the unique axis (φ=0) the coercive field is maximum and is equal to the anisotropy field, H_{C}/H_{A}=1, and the remanent magnetization is equal to the saturation magnetization, M_{R}/M_{S}=1, shown by the dashed, square curve in FIG. 3(c). As the angle between the applied field and the unique axis increases, the coercive field and remanent magnetization collapse, both reaching zero for a field applied at right angles to the unique axis. The Stoner-Wohlfarth (SW) model treats small noninteracting single-domain particles possessing uniaxial anisotropy. Although it models particle shapes consisting of ellipsoids of revolution having an easy axis along the semi-major axis of the ellipsoid, it is nevertheless useful for qualitative comparisons to real systems of particles. Results of the SW model predict that for a completely random distribution of easy axis directions of prolate spheroids (oblate spheroids have H_{C}=0), the remanent magnetization is one-half the saturation value, M_{R}/M_{S}=0.50, and the coercive field is approximately one-half the anisotropy field, H_{C}/H_{A}=0.48, shown by the solid curve in FIG. 3(c). However, the hysteresis data of a nanostructured film in FIG. 2, according to one embodiment, shows a larger remanence ratio of M_{R}/M_{S}=0.78. (Note that this measured ratio is an upper limit as the saturation moment may be larger due to incomplete saturation at the accessible fields.) The larger observed M_{R}/M_{S} ratio may be assigned to partial nonrandom alignment of the easy axes, which is confirmed by the spotty RHEED images (in FIG. 1(c)). This remanence value is equal to that of a SW particle with its unique axis oriented at φ=40 deg to the applied field, where M_{R}/M_{S}=0.77 and H_{C}/H_{A}=0.50, and shown by the dotted curve in FIG. 3(c). Using an upper limit value of H_{C}/H_{A}=0.5 and the observed value of μₒH_{C}=2.5 T, a lower limit for the anisotropy field is estimated to be μₒH_{A}≧5 T for one or more embodiments of the nanostructured film, consistent with extrapolated measurements.

### Sources of Anisotropy

Other contributions to the coercive field were considered. The uniaxial anisotropy is not limited to magnetocrystalline anisotropy, K₁, arising from spin-orbit interactions, but can also have contributions from shape, stress, and surface uniaxial magnetic anisotropies. The shape contribution to the coercive field was estimated to be negligible (˜0.05 T) and the surface contribution was small (≦0.4 T). For the strain contribution, the Williamson-Hall model was applied of XRD line broadening to the data in FIG. 1(d) to obtain a value of RMS strain ε=0.5±0.1%. Although the magnitude of the magnetostriction is not known, the strain could add noticeably to the coercive field (˜100 T). However, the dominant anisotropy leading to the high coercive fields appears to be the magnetocrystalline anisotropy, but strain and surface contributions may be playing a smaller role.

The foregoing discussion should be understood as illustrative and should not be considered to be limiting in any sense. While the inventions have been particularly shown and described with references to preferred embodiments thereof, it will be understood by those skilled in the art that various changes in form and details may be made therein without departing from the spirit and scope of the inventions as defined by the claims.

The corresponding structures, materials, acts and equivalents of all means or step plus function elements in the claims below are intended to include any structure, material, or acts for performing the functions in combination with other claimed elements as specifically claimed.

What is claimed is:

1. A magnetic material comprising:
a rare-earth free, noble-metal-free magnetocrystalline, ferromagnetic thin film disposed on a non-epitaxial substrate, wherein
the thin film comprises a plurality of single-magnetic-domain islands, and
the coercivity of the thin film is greater than that of epitaxially-deposited thin-film samples of rare-earth-free magnetic materials.

2. The material of claim 1, wherein the thin film is a ferrimagnetic compound with tetragonal crystal symmetry.

3. The material of claim 1, wherein the thin film composition is MnₓY, wherein Y is one or more of Al, Ga, Ti, Fe, Co, Cr, V and x is between 1 and 3.

4. The material of claim 1, wherein the coercivity is 2.5-5 T.

5. The material of claim 1, wherein the islands are nanoscale.

6. The material of claim 1, wherein the islands are magnetically isolated.

7. The material of claim 1, wherein the islands are 20-100 nm in diameter.

8. The material of claim 1, wherein the islands are 20-60 nm in diameter.

9. The material of claim 1, wherein the remnant magnetization of the material is greater than one-half of saturation magnetization.

10. A magnetic material comprising:
a rare-earth free, noble-metal-free magnetocrystalline, ferromagnic thin film disposed on a non-epitaxial substrate, wherein
the thin film comprises a plurality of single-magnetic-domain islands and the magnetic domains are aligned with respect to each other.

11. The material of claim 10, wherein the magnetic domains are aligned perpendicular to the thin film thickness.

12. The material of claim 10, wherein the coercivity of the thin film is greater than that of epitaxially-deposited thin-film samples of rare-earth-free magnetic materials

13. The material of claim 10, wherein the coercivity of the thin film is 2.5-5 T.

14. The material of claim 10, wherein the thin film is a ferrimagnetic compound with tetragonal crystal symmetry.

15. The material of claim 10, wherein the thin film composition is MnₓY, wherein Y is one or more of Al, Ga, Ti, Fe, Co, Cr, V and x is between 1 and 3.

16. The material of claim 10, wherein the coercivity is 2.5-5 T.

17. The material of claim 10, wherein the islands are nanoscale.

18. The material of claim 10, wherein the islands are magnetically isolated.

19. The material of claim 10, wherein the islands are 20-100 nm in diameter.

20. The material of claim 10, wherein the islands are 20-60 nm in diameter.

21. The material of claim 10, wherein the remnant magnetization of the material is greater than one-half of saturation magnetization.

22. A method of producing a magnetic material comprising:
depositing a noble-metal-free, rare-earth-free, magnetocrystalline, ferromagnetic thin film on a non-epitaxial substrate to form a plurality of single-magnetic-domain islands, and
annealing the thin film.

23. The method of claim 22, wherein the thin film is a ferrimagnetic compound with tetragonal crystal symmetry.

24. The method of claim 22, wherein the thin film composition is MnₓY, wherein Y is one or more of Al, Ga, Ti, Fe, Co, Cr, V and x is between 1 and 3.

25. The method of claim 22, wherein the coercivity of the material is 2.5-5 T.

26. The method of claim 22, wherein the islands are magnetically isolated and are 20-100 nm in diameter.

27. The method of claim 22, wherein depositing comprises one of molecular beam epitaxy, magnetron sputtering, electron bean evaporation, ion beam deposition, and chemical vapor deposition.

28. The method of claim 22, wherein the depositing is performed at 100-200° C.

29. The method of claim 22, wherein the annealing is performed below 450° C.

30. The method of claim 22, wherein the annealing is performed at 300-400° C.

31. The method of claim 22, wherein the substrate comprises silicon with amorphous native oxide layer or silica.

32. The method of claim 22, wherein annealing aligns the magnetic domains with respect to the each other.

33. The method of claim 22, wherein an external magnetic field is applied during growth or annealing to align the magnetic domains.
